(19) United States
(12) Patent Application Publication
(10) Pub. No.: US 2023/0266671 A1
(43) Pub. Date: Aug. 24, 2023

(54) Amine Oxides for Etching, Stripping and Cleaning Applications

(71) Applicant: Huntsman Petrochemical LLC, The Woodlands, TX (US)

(72) Inventors: Hui Zhou, The Woodlands, TX (US); Michael McCormick, The Woodlands, TX (US); Juventino Uriarte, The Woodlands, TX (US); Ke Zhang, The Woodlands, TX (US)

(21) Appl. No.: 18/020,313

(22) PCT Filed: Aug. 16, 2021
(86) PCT No.: PCT/US2021/046092

§ 371 Date: Feb. 8, 2023

Related U.S. Application Data
(60) Provisional application No. 63/196,250, filed on Jun. 3, 2021.
(60) Provisional application No. 63/070,727, filed on Aug. 26, 2020.

(51) Int. Cl. G03F 7/42

(52) U.S. Cl. CPC G03F 7/425

(57) ABSTRACT

The present disclosure is directed to a method of cleaning a microelectronic substrate, such as a semiconductor device, by contacting the microelectronic substrate with an amine oxide selected from the group consisting of N,N-dimethylethanolamine N-oxide, triethanolamine N-oxide, ethanamine, 2,2′-oxybis[N,N-dimethyl-,N,N′-dioxide], 1-methylpyrrolidine N-oxide, N,N-dimethylcyclohexylamine N-oxide, and a mixture thereof for a time and at a temperature sufficient to clean the substrate.

### CROSS-REFERENCE TO RELATED APPLICATION

Not Applicable.

### TECHNICAL FIELD

The present disclosure generally relates to methods for treating the surface of a semiconductor substrate with an amine oxide. In particular, the present disclosure provides methods for cleaning, stripping or etching the surface of the semiconductor substrate by contacting the semiconductor substrate with an amine oxide.

### BACKGROUND

During the manufacture of electronic devices, such as integrated circuits (IC) and transistors, layers of electronic components and their connectors are etched or deposited onto the surface of a semiconductor substrate, also referred to as a slice or wafer. One factor affecting the quality of the components produced is the cleanliness of the surface of the substrate prior to etching or deposition as impurities or contaminants will become trapped between layers affecting the adhesion between those layers. As advances in technology decrease the size of electrical components and circuits, there is an even greater need to ensure the cleanliness of the substrate surface in order to improve electrical properties and reliability of the manufactured device.

Surface contaminants which may be present include organic compounds (such as grease or solvent vapours), ionic materials, metal oxides/hydroxides, photoresists or silicon particles. Chemical cleaning, etching and stripping methods are commonly used to remove these undesired substances to yield a substantially clean surface prior to further processing. Oxidizers, such as hydrogen peroxide, are widely used in formulations for the etching, stripping and cleaning processes described above, often in conjunction with an acid or base, such as ammonia. However, hydrogen peroxide is known to be thermally or chemically unstable at high or low pH levels. Furthermore, in some instances, hydrogen peroxide may be unsuitable as its high oxidation strength may cause damage to metals or dielectric materials, photoresists and organics. Thus, there is a need for organic oxidizers having low toxicity and a range of oxidation strengths that are compatible with such materials.

### SUMMARY

In an aspect of the present disclosure, there is generally provided a method of cleaning a microelectronic substrate by contacting the substrate with a composition containing one or more amine oxides including, but not limited to, N,N-dimethylethanolamine N-oxide (CAS #10489-99-3), triethanolamine N-oxide (CAS #7529-23-9), ethanamine, 2,2′-oxybis[N, N-dimethyl-, N, N′-dioxide] (CAS #565236-99-9), 1-methylpyrrolidine N-oxide (CAS 7529-17-1), N,N-dimethylcyclohexylamine N-oxide, and a mixture thereof for a time and at a temperature sufficient to clean the substrate. The method of the present disclosure can be carried out on a variety of substrates including but not limited to a semiconductors such as gallium arsenide, silicon wafers containing process residue, transient and non-transient layers applied in the manufacturing of a semiconductor devices such as integrated circuits, sapphire wafers, microelectromechanical devices (MEMs), and optoelectronic devices.

In some embodiments, the substrate has a photoresist layer formed thereon, and the cleaning step removes photoresist from the substrate.

In other embodiments, the substrate has etch residue deposited thereon, and the cleaning step removes etch residue from the substrate.

In still other embodiments, the substrate has ash residue deposited thereon, and the cleaning step removes ash residue from the substrate.

In further embodiments, the substrate has metal residue deposited thereon, and the cleaning step removes metal residue from the substrate.

In still other embodiments, the substrate comprises a dielectric layer such as a low k dielectric material containing an oxide, photoresist or etch residue formed thereon, and the cleaning step partially removes the oxide, and completely removes the photoresist or etch residue from the low k dielectric material.

In some embodiments, the substrate comprises or includes an inorganic oxide containing surface carrying an adhered processing residue, and the composition of the present disclosure chemically etches the inorganic oxide containing surface to facilitate the removal of the adhered processing residue.

### BRIEF DESCRIPTION OF THE DRAWINGS

FIG. 1 is a graph depicting redox potential values for amine oxides of the present disclosure, along with reference values for hydrogen peroxide and N-methylmorpholine oxide; and

FIG. 2 is a graph depicting the relative corrosion rates using hydrogen peroxide, N-methylmorpholine oxide and the amine oxides of the present disclosure.

### DETAILED DESCRIPTION

The following terms shall have the following meanings:

The term “comprising” and derivatives thereof are not intended to exclude the presence of any additional component, step or procedure, whether or not the same is disclosed herein. In order to avoid any doubt, all compositions claimed herein through use of the term “comprising” may include any additional additive or compound, unless stated to the contrary. In contrast, the term, “consisting essentially of” if appearing herein, excludes from the scope of any succeeding recitation any other component, step or procedure, except those that are not essential to operability and the term “consisting of”, if used, excludes any component, step or procedure not specifically delineated or listed. The term “or”, unless stated otherwise, refers to the listed members individually as well as in any combination.

The articles “a” and “an” are used herein to refer to one or to more than one (i.e. to at least one) of the grammatical objects of the article. By way of example, “an amine oxide” means one amine oxide or more than one amine oxide. The phrases “in one embodiment”, “according to one embodiment” and the like generally mean the particular feature, structure, or characteristic following the phrase is included in at least one embodiment of the present disclosure, and may be included in more than one embodiment of the present disclosure. Importantly, such phrases do not necessarily refer to the same aspect. If the specification states a component or feature “may”, “can”, “could”, or “might” be included or have a characteristic, that particular component or feature is not required to be included or have the characteristic.

The term “about” as used herein can allow for a degree of variability in a value or range, for example, it may be within 10%, within 5%, or within 1% of a stated value or of a stated limit of a range.

The terms “preferred” and “preferably” refer to embodiments that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the present disclosure.

The term “optional” or “optionally” means that the subsequently described event, circumstance or material may or may not occur or be present, and that the description includes instances where said event, circumstance or material occurs or is present and instances where it does not occur or is not present.

Values expressed in a range format should be interpreted in a flexible manner to include not only the numerical values explicitly recited as the limits of the range, but to also include all of the individual numerical values or sub-ranges encompassed within that range as if each numerical value and sub-range is explicitly recited. For example, a range such as from 1 to 6, should be considered to have specifically disclosed sub-ranges, such as, from 1 to 3, from 2 to 4, from 3 to 6, etc., as well as individual numbers within that range, for example, 1, 2, 3, 4, 5, and 6. This applies regardless of the breadth of the range.

The terms “low k dielectric material” and “low dielectric constant dielectric material’, as used herein, are intended to refer to a dielectric material having a dielectric constant below about 3.5, and preferably about 2.5 or less. Typically the terms “low k dielectric material’ or “low dielectric constant dielectric material’, as used herein, refer to a dielectric material having a dielectric constant of from as low as about 1.4 to about 3.5. The current disclosure may also be useful in cleaning substrates containing dielectric layers where the k value is between 3.5 and 4.5.

The term “substantially free” refers to a composition in which a particular compound or moiety is present in an amount that has no material effect on the composition. In some embodiments, “substantially free” may refer to a composition in which the particular compound or moiety is present in the composition in an amount of less than 2% by weight, or less than 1% by weight, or less than 0.5% by weight, or less than 0.1% by weight, or less than 0.05% by weight, or even less than 0.01% by weight based on the total weight of the composition, or that no amount of that particular compound or moiety is present in the respective composition.

The amine oxides of the present disclosure have been developed to have different oxidation capability, which surprisingly provides the possibility to selectively oxidize the desired material it is applied to and not damage other materials. Furthermore, the corrosivity of each amine oxide of the present disclosure to different metals, such as Al, Cu, and Co etc. is also slightly different from each another so each can be formulated with or without a corrosion inhibitor in customized formulations for varieties of applications

The present disclosure generally relates to a method for cleaning a microelectronic substrate by contacting the substrate with a composition comprising one or more amine oxides including, but are not limited to, N,N-dimethylethanolamine N-oxide (CAS #10489-99-3), triethanolamine N-oxide (CAS #7529-23-9), ethanamine, 2,2′-oxybis[N, N-dimethyl-, N, N′-dioxide] (CAS #565236-99-9), 1-methylpyrrolidine N-oxide (CAS 7529-17-1), N,N-dimethylcyclohexylamine N-oxide, and a mixture thereof. The amine oxides of the present disclosure have been found to show a range of oxidation capability and are also expected to exhibit acceptable toxicity. Furthermore, because the amine oxides show a range of oxidation capability, they are able to provide different strengths of oxidation which can be used in a variety of compositions to etch, strip and clean different microelectronic substrates, metals, photoresists and organics. The amine oxides of the present disclosure also allow for the design of compositions for use in a specific wet processing step, a specific type or mixture of metal surface, or to obtain a certain desired effect on the microelectronic substrate's surface.

The amine oxides of the present disclosure may be prepared through reaction of the appropriate amine (including, but not limited to, aromatic amines, aliphatic amines, cyclic amines, cyclic aliphatic amines) with an oxidizer such as, but not limited, to hydrogen peroxide. Potentiometric titration with strong acid, such as hydrochloric acid (HCl), may be used to determine the proportion of amine oxide and unreacted amine in the reaction mixture. The amine oxide content may be calculated from the ratio of strong base to the total base.

According to an embodiment, the composition may include at least about 0.01% by weight (for e.g., at least about 0.5% by weight, or at least about 1% by weight, or at least about 2% by weight, or at least about 3% by weight, or at least about 5% by weight) and/or at most about 30% by weight (e.g., at most about 25% by weight, or at most about 20% by weight, or at most about 17% by weight, or at most about 15% by weight, or at most about 12% by weight, or at most about 10% by weight) of the amine oxide, where the % by weight is based on the total weight of the composition. In still another embodiment, the composition is substantially free of hydrogen peroxide.

The compositions of the present disclosure may also include other materials known to those skilled in the art which are used to clean, etch or strip the surface of a microelectronic substrate. Such materials include, but are not limited to: organic solvents; water; metal halides, hydroxides, borides, alkoxides, oxides and ammonium salts; organic acids; pH adjusting agents; corrosion inhibitors; surfactants; biocides; defoaming agents; chelating agents; and antimicrobial agents.

The compositions containing the amine oxides of the present disclosure are used to clean the surface of the substrate, such as semiconductors, glass, metals, ceramic materials, resins, magnetic materials, superconductors, etc., which tend to undergo significant problems by contamination with metals or particles. In particular, the compositions containing the amine oxides of the present disclosure are more suitably used to clean the surface of semiconductor devices such as semiconductor elements and display devices, which are required to have a highly cleaned surface, upon production of the substrate for semiconductor devices. These substrates may be provided on the surface thereof with wiring and electrodes, insulating materials, low k dielectric materials, metal oxides, organic compounds and metals. Examples of materials for the wiring and electrodes may include semiconductor materials such as Si, Ge, Ga and As; insulating materials such as SiO₂, silicon nitride, glass, metal oxides such as copper or aluminum oxide, transition metal oxides such as titanium oxide, tantalum oxide, hafnium oxide and zirconium oxide, (Ba,Sr)TiO₃ (BST), organic compounds such as polyimides, and organic thermosetting resins; metals such as W, Cu and Al or alloys, silicides and nitrides thereof or the like.

In particular, the compositions containing the amine oxides of the present disclosure are suitably used for cleaning semiconductor devices, which have transition metals or transition metal compounds on the surface thereof. Examples of the transition metals may include tungsten, copper, aluminum, titanium, chromium cobalt, zirconium, hafnium, molybdenum, ruthenium, gold, platinum, silver, etc. Examples of the transition metal compounds may include nitrides, oxides, and silicides.

According to one embodiment, the method of the present disclosure includes a step of contacting the composition containing the amine oxides above with a substrate that includes a layer of photoresist, an anti-reflective coating layer, inorganic or organic contaminants such as polymers based on stryenic, acrylic, novolac, cyclic olefinic or maleic anhydride resins, etch and ash residue based on ions of fluorine, chlorine, bromine or iodine, and oxygen; metallic impurities containing tantalum, titanium, copper, aluminum or tungsten or slurry residue containing silica or alumina abrasives with other common slurry additives such as oxidizers, buffers, stabilizers, surfactants, passivating agents, complexing agents, corrosion inhibitors or other agents.

The cleaning method used in the present disclosure may be performed by directly contacting the composition with the substrate. As the method of contacting the composition containing the amine oxides above with the substrate, there may be used a dip-type contacting method in which the substrate is dipped in a cleaning tank filled with the composition, a spin-type contacting method in which the substrate is rotated at a high speed while flowing the composition from a nozzle onto the substrate, a spray-type contacting method in which the substrate is cleaned by spraying the composition thereonto, or the like. As an apparatus for performing the above cleaning methods, there may be used a batch-type cleaning apparatus in which a plurality of substrates accommodated in a cassette are cleaned at the same time, a single wafer-type cleaning apparatus in which a single substrate fitted to a holder is cleaned, or the like.

The cleaning time is usually from 30 sec to 30 min, preferably from 1 to 15 min for the batch-type cleaning apparatus, and usually from 1 sec to 15 min, preferably from 5 sec to 5 min for the single wafer-type cleaning apparatus. When the cleaning time is too short, it may be difficult to attain a sufficient cleaning effect. When the cleaning time is too long, the corresponding cleaning effect is not attainable, thereby causing deterioration in throughput. The composition containing the amine oxides of the present disclosure may be applied to the substrate by any of the above methods. From the standpoint of removing contaminants more efficiently for a short period of time, the use of the spin-type or spray-type cleaning method may be more preferred. In addition, when the composition of the present disclosure is applied to the single wafer-type cleaning apparatus having problems concerning shortening of cleaning time and reduction in amount of the cleaning solution used, these problems may be suitably eliminated.

The temperature of the composition used in the methods above is usually room temperature. In order to enhance the cleaning effect, the composition may be heated to a temperature of about 40° to 70° C. Further, when the substrate to be cleaned has silicon exposed onto the surface thereof, residual organic contaminants tend to be deposited on the surface of the silicon. Therefore, in such a case, it is preferred that the cleaned substrate is heat-treated at a temperature of not less than 300° C. to heat-decompose the organic deposited, or subjected to ozone water treatment to oxidation-decom pose the organic deposited.

Also, the cleaning method of the present disclosure may be preferably used in combination with the physical cleaning method, for example, mechanical cleaning method such as scrub-cleaning using a cleaning brush or megasonic cleaning method. In particular, when megasonic irradiation or brush-scrubbing is used in combination with the composition containing the amine oxides of the present disclosure, the particle contaminant removability is further enhanced, leading to reduction in cleaning time. In addition, the cleaning after chemical mechanical polishing is preferably conducted using a brush made of resins.

The resin material of the brush may be optionally selected, for example, the brush may be prepared from PVA (polyvinyl alcohol). Also, when the substrate is irradiated with a megasonic wave having a frequency of not less than 0.5 MHz, the particle contaminant removability can be remarkably enhanced owing to the synergistic effect with the amine oxide. Further, prior to and/or subsequent to conducting the cleaning method of the present invention, the substrate may be cleaned with electrolytic ionized water obtained by electrolysis of water, or hydrogen water prepared by dissolving a hydrogen gas in water.

In another embodiment, the present disclosure also includes a cleaning method used in combination with the following photoresist stripping processes, which are typically conducted prior to the present cleaning method. Any suitable dry stripping process can be used including O₂ plasma ashing, ozone gas phase-treatment, fluorine plasma treatment, hot H₂ gas treatment and the like.

In addition, the cleaning method can also be used in combination with an organic wet stripping method. The organic wet strip can be performed either before, after, or both before and after the cleaning method of the present disclosure. Any conventional organic wet stripping solution can be used and a person skilled in the art would be able to choose the appropriate organic wet stripper.

According to another embodiment, the composition of the present disclosure may be used for cleaning semiconductor substrates after chemical mechanical planarization or polishing of metal films. Thus, the method of the present disclosure is directed to cleaning planarized surfaces of a semiconductor wafer having metallic features (conductive features), such as interlayer connectors or conducting lines. The surface can comprise, for example, a metal such as copper, aluminum, platinum, titanium, silver, tungsten and/or tantalum, a dielectric material such as silica, borophosphosilicate glass (BPSG), borosilicate glass (BSG), or phosphosilicate glass, carbon-doped silica, porous silica, and/or a low k dielectric material such as silicon dioxide deposited by plasma enhanced chemical vapor deposition (PECVD), a spin-coat process, or decomposition from a tetraethylorthosilicate (TEOS) precursor. After such a wafer has been planarized, residual particles, for example, from the slurry, metal features, dielectric material, pad and wafer, remain loose on the planarized surface. The method comprises contacting the planarized surface of the wafer with a composition comprising the amine oxides of the present disclosure at a temperature and for a time (such as those described above) effective to remove at least a portion of the residual particles from the planarized surface of the wafer. In an embodiment of the method of the present disclosure, the composition is applied to a semiconductor substrate after the formation of copper or aluminum interconnects and a CMP of the interconnects.

According to another embodiment of the present disclosure the surface of a semiconductor substrate is treated using an amine oxide to clean the surface by removing contaminants, for example organic compounds, oxide layers and ionic substances.

According to an embodiment of the present disclosure the surface of a semiconductor substrate is treated with an amine oxide to strip the surface of a photoresist layer that is no longer required, for example once an etching stage has been completed.

According to still another embodiment of the present disclosure the surface of a semiconductor substrate is treated with an amine oxide to etch the surface in order to chemically remove a layer or layers of the substrate. In some embodiments, part of the substrate may be protected with a masking material which resists etching, such as silicon nitride.

It has been surprisingly found that the amine oxides of the present disclosure exhibit a range of oxidation strengths that are less than that of hydrogen peroxide. It is well known that the powerful oxidative power of hydrogen peroxide can cause undesirable damage to metals, photoresists and organics during the manufacture of semiconductor devices. This means that the amine oxides of the present disclosure are compatible with a wider range of metals, photoresists and organics and can be used for stripping, cleaning and etching treatments on a wider range of semiconductor substrates without causing undesirable damage. Furthermore, these amine oxides are thermally stable in comparison to hydrogen peroxide, meaning that they will have a longer shelf life. Thus, in still another there is provide a composition containing the amine oxides of the present disclosure and where the composition is substantially free of hydrogen peroxide.

### EXAMPLES

### Example 1: Preparation of N,N-Dimethylethanolamine N-Oxide

In a 1.0 L round bottom glass reactor, equipped with agitator, nitrogen line, addition funnel and overhead condenser, 37.0 grams deionized (DI) water and 284.4 grams of dimethylethanolamine were charged. The reactor was heated up to 57° C. (135° F.) after nitrogen was bubbled through for 5 min. Then 350.0 grams of 31% hydrogen peroxide was slowly added while the reaction mass temperature was maintained between 57-60° C. (135-140° F.). After all hydrogen peroxide was charged, the reaction was allowed 60 minutes digestion while maintaining reaction temperature between 57-60° C. (135-140° F.). The reaction was cooled down to room temperature (RT), and the finished product was packed into a 32 oz plastic bottle under a nitrogen pad.

Titration indicated about 99% of dimethylethanolamine has been oxidized.

### Example 2: Preparation of Triethanolamine N-Oxide

In a 1.0 L round bottom glass reactor, equipped with agitator, nitrogen line, addition funnel and overhead condenser, 60 grams DI water and 256.4 grams of triethanolamine was charged. The reactor was heated up to 57° C. (135° F.) after nitrogen was bubbled through for 5 min. Then 278.0 grams of 31% hydrogen peroxide was slowly added while the reaction mass temperature was maintained between 57-60° C. (135-140° F.). After all hydrogen peroxide had been charged, the reaction was allowed 60 minutes digestion while maintaining reaction temperature between 57-60° C. (135-140° F.). Cooled down to RT, and the finished product was packed into a 32 oz plastic bottle under a nitrogen pad.

Titration indicated about 99% of triethanolamine has been oxidized.

### Example 3: Preparation of Ethanamine, 2,2′-Oxybis[N,N-Dimethyl-, N,N′-Dioxide]

In a 1.0 L round bottom glass reactor, equipped with agitator, nitrogen line, addition funnel and overhead condenser, 10.0 grams DI water and 277.6 grams of bis-(2-dimethylaminoethyl)ether was charged. The reactor was heated up to 57° C. after nitrogen was bubbled through for 5 min. Then 280.0 grams of 31% hydrogen peroxide was slowly added while reaction mass temperature was maintained between 57-60° C. (135-140° F.). After all hydrogen peroxide was charged, the reaction was allowed 60 minutes digestion while maintaining reaction temperature between 57-60° C. (135-140° F.). Cooled down to RT, and the finished product was packed into a 32 oz plastic bottle under a nitrogen pad.

Titration indicated about 95% of bis-(2-dimethylaminoethyl)ether has been oxidized.

### Example 4: Preparation of 1-Methylpyrrolidine N-Oxide (XHE-139)

In a 1.0 L round bottom glass reactor, equipped with agitator, nitrogen line, addition funnel and overhead condenser, 20.5 grams DI water and 232.8 grams of 1-methylpyrrolidine was charged. The reactor was headed up to 57° C. after nitrogen was bubbled through for 5 mins. Then 300.0 grams of 31% hydrogen peroxide was slowly added while reaction mass temperature was maintained between 57-60° C. (135-140° F.). After all hydrogen peroxide was charged, the reaction was allowed 60 minutes digestion while maintaining reaction temperature between 57-60° C. (135-140° F.). Cooled down to RT, and the finished product was packed into a 32 oz plastic bottle under a nitrogen pad.

Titration indicated about 99% of 1-methylpyrrolidine has been oxidized.

### Example 5: Preparation of N,N-Dimethylcyclohexylamine N-Oxide

In a 1.0 L round bottom glass reactor, equipped with agitator, nitrogen line, addition funnel and overhead condenser, 114.0 grams DI water and 289.9 grams of N,N-dimethylcyclohexylamine was charged. The reactor was heated up to 57° C. after nitrogen was bubbled through for 5 min. Then 250.0 grams of 31% hydrogen peroxide was slowly added while reaction mass temperature was maintained between 57-60° C. (135-140° F.). After all hydrogen peroxide was charged, the reaction was allowed 60 minutes digestion while maintaining reaction temperature between 57-60° C. (135-140° F.). Cooled down to RT, and the finished product was packed into a 30 oz plastic bottle under a nitrogen pad.

Titration indicated about 72% of N,N-dimethylcyclohexylamine has been oxidized.

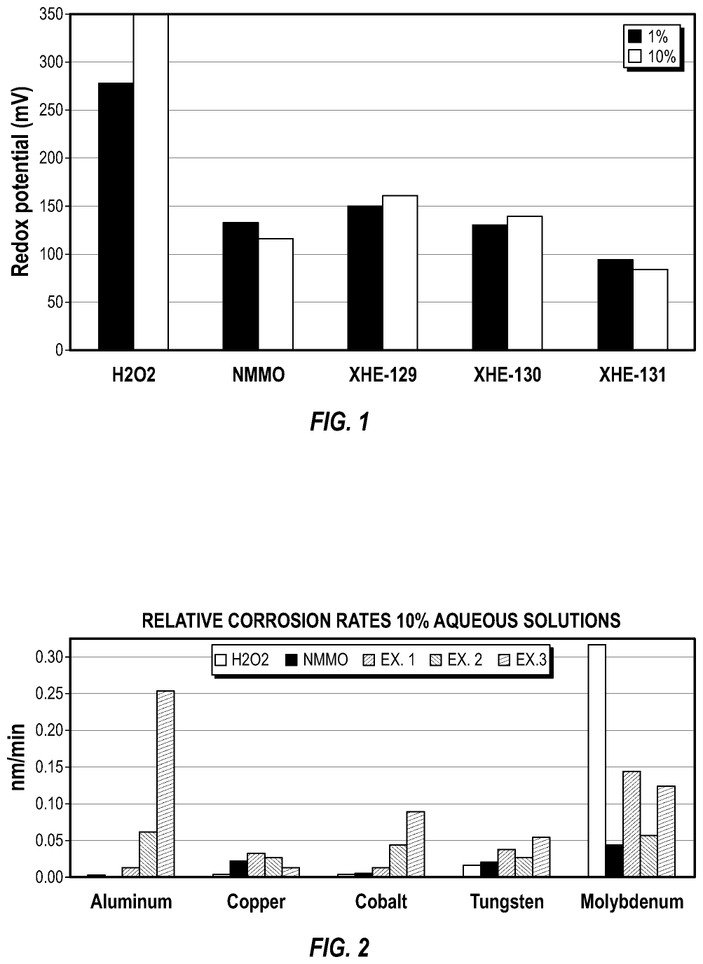

With reference to FIG. 1, the redox potential for N,N-Dimethylethanolamine N-oxide (Ex. 1), Triethanolamine N-oxide (Ex. 2) and Ethanamine, 2,2′-oxybis[N,N-dimethyl-, N,N′-dioxide] (Ex. 3) are shown, along reference values for hydrogen peroxide (H₂O₂) and N-Methylmorpholine-N-oxide (NMMO). The redox potentials for the amine oxides of the present disclosure are shown to be lower than those of hydrogen peroxide, but greater than those of N-methylmorpholine oxide.

With reference to FIG. 2, the corrosion rates for the above amine oxides are shown as well as N-methylmorpholine oxide and hydrogen peroxide for different metals. The corrosion rates for the amine oxides of the present disclosure are shown to be less than those for hydrogen peroxide.

Of course, the above described embodiments are intended to be illustrative only and in no way limiting. The described embodiments of carrying out the invention are susceptible to many modifications of form, arrangement of parts, details, and order of operation. The invention, therefore, is intended to encompass all such modifications within its scope.

What is claimed is:

1. A method for cleaning a microelectronic substrate comprising contacting the substrate with a composition comprising an amine oxide selected from the group consisting of triethanolamine N-oxide N,N-dimethylethanolamine, N-oxide, ethanamine, 2,2′-oxybis[N, N-dimethyl-, N, N′-dioxide], 1-methylpyrrolidine N-oxide, N, N-dimethylcyclohexylamine N-oxide, and mixtures thereof.

2. The method of claim 1, wherein the microelectronic substrate comprises a semiconductor, glass, a metal, a ceramic material, a resin, a magnetic material or a superconductor.

3. The method of claim 1, wherein the microelectronic substrate comprises a semiconductor provided on the surface thereof with wiring and electrodes, insulating materials, low k dielectric materials, metal oxides, organic compounds or metals.

4. The method of claim 3, wherein the wiring and electrodes comprise silicon, germanium, gallium, arsenide; the insulating materials comprise SiO₂, silicon nitride or glass; the metal oxides comprise copper oxide, aluminum oxide, titanium oxide, tantalum oxide, hafnium oxide, zirconium oxide or (Ba,Sr)TiO₃, the organic compounds comprise polyimides or organic thermosetting resins; and the metals comprise tungsten, copper, aluminum or alloys, silicides and nitrides thereof.

5. The method of claim 1, wherein the microelectronic substrate has a photoresist layer formed thereon, and the contacting of the substrate with the composition removes the photoresist layer from the substrate.

6. The method of claim 1, wherein the microelectronic substrate has ash residue deposited thereon, and the contacting of the substrate with the composition removes the ash residue from the substrate.

7. The method of claim 1, wherein the microelectronic substrate has etch residue deposited thereon, and the contacting of the substrate with the composition removes the etch residue from the substrate.

8. The method of claim 1, wherein the microelectronic substrate has metal residue deposited thereon, and the contacting of the substrate with the composition removes the metal residue from the substrate.

9. The method of claim 1, wherein the microelectronic substrate comprises a low k dielectric material containing an oxide, photoresist or etch residue formed thereon, and the contacting of the substrate with the composition partially removes the oxide, and completely removes the photoresist or etch residue from the low k dielectric material.

10. The method of claim 1, wherein the microelectronic substrate the comprises an inorganic oxide containing surface carrying an adhered processing residue, and the contacting of the substrate with the composition chemically etches the inorganic oxide containing surface to facilitate the removal of the adhered processing residue.

11. The method of claim 1, wherein the composition is substantially free of hydrogen peroxide.
